(19) United States
(12) Patent Application Publication
(10) Pub. No.: US 2014/0043780 A1
(43) Pub. Date: Feb. 13, 2014

(54) HYBRID PORTABLE POWER SUPPLY

(71) Applicant: East Rule Technology Co., Ltd., Zhubei City (TW)

(72) Inventors: MING-HUNG TSAI, Zhubei City (TW); KUANG LEE, Zhubei City (TW); JIANG ZHI-ZHONG, Zhubei City (TW); DONG-LIANG HUANG, Zhubei City (TW); SHI-YU WENG, Zhubei City (TW)

(73) Assignee: East Rule Technology Co., Ltd., Zhubei City (TW)

(21) Appl. No.: 13/960,902

(22) Filed: Aug. 7, 2013

(30) Foreign Application Priority Data
Aug. 9, 2012 (TW) 101215309

(51) Int. Cl. H05K 5/00

(52) U.S. Cl. CPC H05K 5/0026
USPC 361/752

(57) ABSTRACT

The present invention provides a hybrid portable power supply. In addition to providing emergency power to vehicles, the portable power supply of this invention integrates multiple functions, including lighting, warning, self-test and circuit protection. Moreover, the design of the power supply's housing is compact and aesthetically pleasing, making this power supply highly portable and easy for organizing cables.

### BACKGROUND OF THE INVENTION

1. Field of the Invention

The present invention relates to an emergency power supply for vehicles, and more particularly, to a multi-functional emergency power supply for vehicles.

2. Description of the Prior Art

When a vehicle cannot be started due to power outage, a conventional solution is to connect the disabled vehicle's car battery to another vehicle's car battery with jumper cables. Another way to solve the problem is to request emergency roadside assistance for battery jump starts. However, both solutions are somehow tiring and time-consuming.

To solve the inconvenience described above, and to solve other problems related to jump starting a vehicle by connecting the batteries of two cars, various portable power supplies have been designed, and many of them are still improving. Some examples of portable power supplies are given below. Taiwanese Utility Model Patent No. 460091 discloses a Portable Rescue Power Supply. In this patent, the internal car battery can be removed separately from the power supply device to provide emergency power to a vehicle. Moreover, the power supply device is provided with a circuit control system which enables the device to disconnect from a car's computer system while providing emergency power, so that damage to the computer system is avoided. Taiwanese Utility Model Patent No. M381557 discloses a Vehicle Charging Rescue Apparatus. The apparatus comprises a housing specifically designed to retain all the constituent parts within the housing to protect them; meanwhile, the cables and clamps are also retained within the housing and thus compose a compact and convenient charging apparatus.

Taiwanese Utility Model Patent No. M423638 discloses a Composite Multi-functional Rescue Assembly aiming at multi-purpose applications. The assembly comprises two housings connected to each other, and the housings enclose a circuit board provided with a power contact, indicators, a startup switch, and input/output devices. The assembly is not only compact and portable, but is a convenient apparatus that allows users to replace or change the input/output devices as needed, so that the rechargeable battery of the assembly can supply power to different kinds of electrical appliances.

Lately, needs for multi-purpose applications and for ensured safety during the supply of power are factors that need to be considered in designing an emergency power supply for vehicles. For example, in addition to an attractive appearance, one such power supply may need to feature easy organization and storage of jumper cables, to have a lighting function, and to allow charging for various electrical/electronic equipments. Moreover, to properly protect a car's computer system from harm during the supply of emergency power, it is also important to equip the power supply with an automatic circuit breaker and warning device.

Given the foregoing, the present invention provides a novel hybrid portable power supply. The hybrid portable power supply of this invention can be used for emergency power supply, and it satisfies the additional requirements described above.

### SUMMARY OF THE INVENTION

The hybrid portable power supply of the present invention satisfies the various needs, as discussed above, for an emergency power supply for vehicles.

In addition to providing emergency power to vehicles, the portable power supply of this invention integrates multiple functions, including lighting, warning, self-test and circuit protection. Moreover, the design of the power supply's housing is compact and aesthetically pleasing, making this power supply highly portable and easy for organizing cables.

According to an aspect of the invention, the portable power supply comprises a housing; the housing encloses at least one rechargeable and dischargeable battery and integrates a control circuit board, which is connected to a panel of the housing. The panel is provided with a plurality of power input/output connectors, a self-test switch, a circuit reset switch, an alarm device, a lighting device, and a charging connector.

Preferably, the control circuit board operates to control rectification and voltage conversion of power output from the rechargeable and dischargeable battery, such that power having at least a corresponding current or power having at least a corresponding voltage is output via one of the plurality of power input/output connectors.

Preferably, the plurality of power input/output connectors include an emergency power connector via which power having a high instantaneous power value is output for supplying emergency power to vehicles.

Preferably, the emergency power connector is connected to a power input port of a vehicle in need of emergency power by a removable power cable. Moreover, the emergency power connector is a modular quick connector having a foolproof mechanism.

Preferably, the rechargeable and dischargeable battery is a LiFePO₄ battery.

Preferably, the control circuit board is provided with a rectifier module and a voltage converter module to accordingly adjust a current value or a voltage value of the power output from the rechargeable and dischargeable battery.

Preferably, the control circuit board operates to control the rectification and the voltage conversion of the power output from the rechargeable and dischargeable battery, such that one of the following power outputs is generated: power having a voltage of 5V, power having a voltage of 12V, power having a specified current value, and the power having a high instantaneous power value.

Preferably, the plurality of power input/output connectors further include at least one of a USB DC power outlet, a constant current power outlet, and a vehicle cigarette lighter outlet.

Preferably, the control circuit board is provided with a self-test module which is coupled to and activated by the self-test switch to test and display the rechargeable and dischargeable battery's power level.

Preferably, the control circuit board is provided with a circuit reset module which is coupled to and activated by the circuit reset switch to control the resetting of the portable power supply.

Preferably, the control circuit board is provided with a circuit breaker module which automatically cuts off power under one of the following circumstances: there is a short circuit in the portable power supply; there is a misconnection between the portable power supply and the vehicle in need of emergency power; the rechargeable and dischargeable battery is overcharged; and the rechargeable and dischargeable battery is over-discharged.

Preferably, the alarm device is a buzzer which gives a warning tone in response to one of the following conditions: there is a short circuit in the portable power supply; and the rechargeable and dischargeable battery has a power level lower than a predetermined one.

Preferably, the alarm device is an LED device comprising a plurality of LEDs, and the LED device activates a corresponding number of the LEDs to emit light according to a power level of the rechargeable and dischargeable battery.

Preferably, the lighting device includes a multi-level lighting device; preferably, the lighting device can provide a desired illumination level, such as 100%, 50%, and 30% illumination, depending on ambient conditions or actual needs.

Preferably, the lighting device flashes on and off to give a warning in response to an emergency event.

Preferably, the charging connector is adaptable to the following charging sources: a household electrical outlet, a power source compatible with universal voltage, a vehicle charging circuit, and a vehicle cigarette lighter.

Preferably, the housing is formed by connecting a first housing and a second housing, and wherein the first housing is provided with a handle.

In addition to providing emergency power for vehicles, the portable power supply of the present invention can also function as a power supply or charging source supporting different voltage/current outputs for various electronic/electrical appliances. Moreover, the portable power supply of the present invention uses a high-power LiFePO₄ rechargeable battery, which can be recharged by connecting to AC mains power via an adapter, to a vehicle cigarette lighter outlet, or to a 12V high instantaneous power outlet.

### BRIEF DESCRIPTION OF THE DRAWINGS

FIG. 1 is a perspective view of a hybrid portable power supply according to the present invention.

FIG. 2 is an exploded view of the hybrid portable power supply as shown in FIG. 1.

FIG. 3 is a perspective view of a panel on a housing of the hybrid portable power supply as shown in FIG. 1.

FIG. 4 is an exploded view of the panel as shown in FIG. 3.

### DETAILED DESCRIPTION OF THE PREFERRED EMBODIMENTS

While this invention will be fully described with preferred embodiments and the appended drawings, it is to be understood beforehand that those skilled in the art can make modification to the invention described herein and attain the same effect. Therefore, it is to be understood that the description below is a general representation to those skilled in the art and is not intended to limit the scope of the present creation.

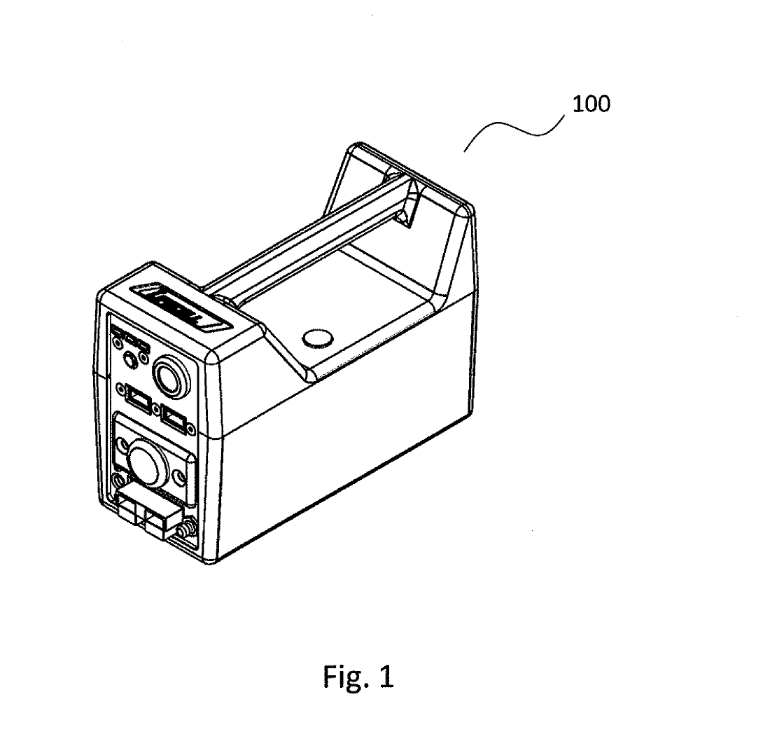

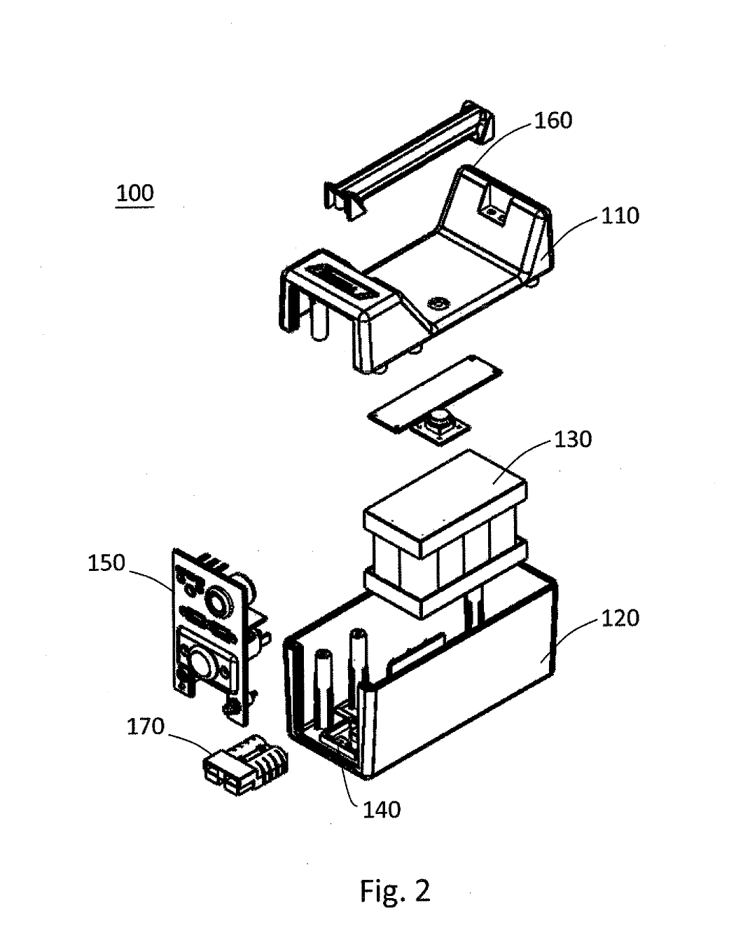

FIG. 1 shows a perspective view of a hybrid portable power supply 100 (hereinafter referred to as the “power supply 100”) according to an embodiment of the present invention, and FIG. 2 shows an exploded view of the same. As FIG. 2 shows, the power supply 100 mainly comprises a housing, which is formed by connecting a first housing 110 to a second housing 120, and a rechargeable and dischargeable battery 130 enclosed in the housing. The rechargeable and dischargeable battery 130 may be a single high-power battery, such as a LiFePO₄ battery. In an alternative embodiment, the power may be provided by plural rechargeable and dischargeable batteries connected in series and in parallel as needed, so that high-power electricity can be output.

In the embodiment shown in both FIGS. 1 and 2, the first housing 110 of the power supply 100 is provided with a handle 160 for the user to carry it. A control circuit board 140 is located within the housing and coupled to a panel 150 of the power supply 100; the user can control the operations of the power supply 100 through the panel 150. The control circuit board 140 operates to control the rectification and voltage conversion of the power output from the rechargeable and dischargeable battery 130, so that power having at least a corresponding current or power having at least a corresponding voltage is output.

The primary role of the power supply 100 according to the present invention is to supply emergency power to vehicles. The power supply 100 includes an emergency power supply connector, which is a modular quick connector 170. A removable power cable (not shown) connects the modular quick connector 170 and a power input port (not shown) of a vehicle in need of emergency power, so that power having a high instantaneous power value is output to the vehicle. Preferably, the modular quick connector 170 has a foolproof mechanism in case an improper connection of power terminals or a short circuit occurs.

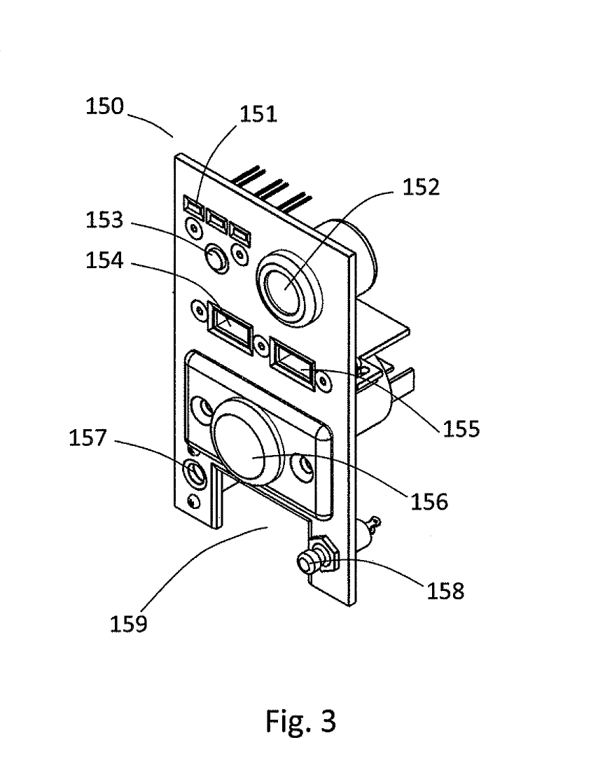

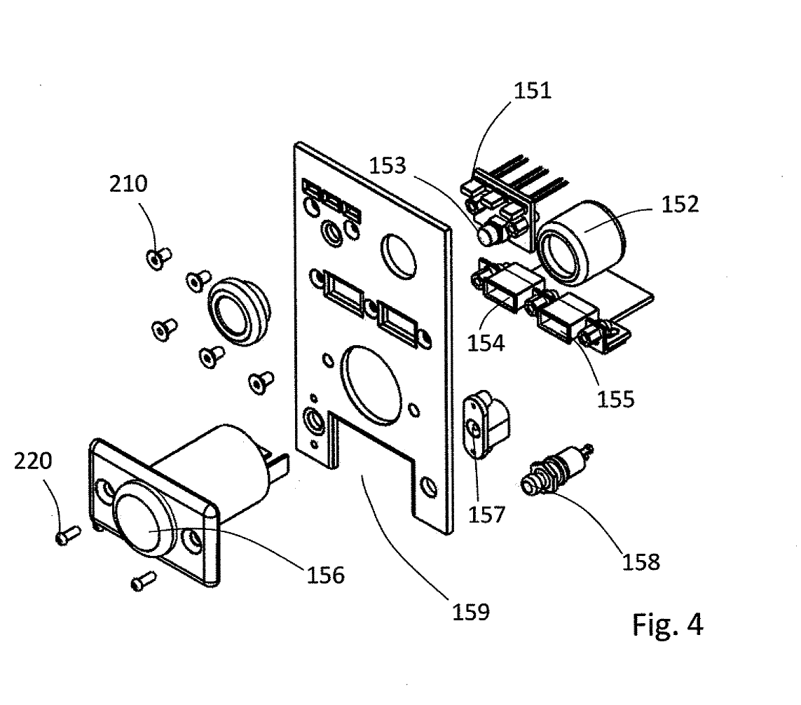

FIG. 3 and FIG. 4 show a perspective view and an exploded view, respectively, of a panel on the hybrid portable power supply according to an embodiment of the present invention. As FIG. 3 shows, the panel 150 on the power supply 100 has an alarm device 151 composed of LEDs to indicate power level, a lighting device (a light) 152, a self-test switch 153, a plurality of power input/output connectors 154-156, a charging connector 157, and a circuit reset switch 158. These parts are secured to the panel 150 by suitable securing members 210 and 220 (e.g., screws). Moreover, the panel 150 has an opening 159 to adapt the modular quick connector 170 (shown in FIG. 2).

In a preferred embodiment of the present invention, when the self-test switch 153 on the panel 150 is turned on, the power supply 100 (shown in FIG. 2) starts testing the power level of the rechargeable and dischargeable battery 130 (shown in FIG. 2). Then, in accordance with the power level detected, a corresponding number of the LEDs of the alarm device 151 will emit light to indicate the power level. That is, in response to the power level detected, the LED alarm device 151 activates a corresponding number of the LEDs to emit light. For example, when the power level is detected to be full, the LED alarm device 151 activates three LEDs to emit light, indicating the battery is fully charged. When the power level of the battery is lower than a predetermined one, the LED alarm device 151 activates one LED only in response to the low power level. In the present invention, the predetermined level of power allows one to three chargings.

According to the present invention, the LED alarm device 151 is an alarm device composed of plural LEDs. Besides, the power supply has a separate lighting device (a light) 152 for lighting purpose. The lighting device 152 can provide a desired illumination level, such as 100%, 50%, and 30% illumination, depending on ambient conditions or actual needs. Moreover, in an emergency, the lighting device 152 may send a Morse code SOS distress signal by giving three short, three long, three short light flashes.

In addition to providing power having a high instantaneous power value to vehicles in need of emergency power via a modular quick connector 170 (as shown in FIG. 2) and cables, the power supply 100 of the present invention can also function as a power source supporting different voltage/current outputs for various electronic/electrical appliances. That is, the power supply 100 can have power outlets such as a USB DC power outlet, a constant current power outlet, or a vehicle cigarette lighter power outlet. For example, the power input/output connector 154 is a USB DC power outlet supplying 5V/1 A power; the power input/output connector 155 is another USB DC power outlet supplying 5V/2.1 A power; and power input/output connector 156 is a 12V cigarette lighter power outlet supplying power to common electronic/electrical appliances with car charging features, such as mobile phones, PDAs, and GPS navigation devices.

The power supply 100 (shown in FIG. 2) of the present invention operates to have the rechargeable and dischargeable battery 130 (shown in FIG. 2) charged via the charging connector 157, which is connected externally to mains power. In the present invention, the charging connector 157 can also be connected to a household electrical outlet or a power source compatible with universal voltage. In addition, the rechargeable and dischargeable battery 130 may obtain charging power from the cigarette lighter via the power input/output connector 156 or from the car charging circuit (not shown) via the modular quick connector 170 (shown in FIG. 2); that is, multiple power sources can be used to charge the power supply 100.

In an alternative embodiment, the control circuit board 140 (shown in FIG. 2) of the power supply 100 is provided with a circuit breaker module. When a short circuit occurs to the power supply 100, or when there is an improper connection of power terminals between the power supply 100 and the battery of a vehicle in need of emergency power, the circuit breaker module will automatically interrupt the circuit to protect the vehicle's computer system or other electronic/electrical appliances against damage. The circuit breaker module may also interrupt the circuit when the rechargeable and dischargeable battery is overcharged or over-discharged. When the circuit is interrupted, the user simply turns on the circuit reset switch to activate the circuit reset module on the control circuit board 140, and the power supply 100 can thus be reset.

In an alternative embodiment, the alarm device of the power supply 100 may be a buzzer instead of an LED device composed of plural LEDs. The buzzer, as the alarm device, gives a warning tone when there is a short circuit in the power supply 100, or when the battery power level is low.

The portable power supply according to the present invention is hybrid. It uses a high-power rechargeable battery which can be charged and discharged repeatedly. Through the use of a control circuit board installed in the portable power supply, power can be supplied in three different outputs, including 5V power for USB ports, 12V power for vehicle cigarette lighter ports, and 12V high instantaneous power for emergency use. On the other hand, the rechargeable battery of the portable power supply can be recharged by connecting to AC mains power via an adapter, to a vehicle cigarette lighter outlet, or to a 12V high instantaneous power outlet.

In addition to the power supply function, the portable power supply of the present invention has a multi-functional lighting device, which is able to provide lighting of multiple illumination levels and to send out warning signals by giving bright, flashing light.

The hybrid portable power supply of the present invention is also incorporated with circuit protection and fast resetting functions. When the control circuit detects that the power supply is not in use for a specified period of time, the circuit will be automatically cut off to minimize power consumption and extend the product life cycle. Also, fast resetting of the circuit can be achieved by using the circuit reset switch to activate the circuit reset module.

The hybrid portable power supply of the present invention uses external, removable power cables (vehicle jumper cables), and thus, the power supply is more compact in size, more portable, and easier to store.

While this creation has been described by way of preferred embodiments, it is to be understood that this creation is not limited hereto, and that various changes and alterations can be made herein by those skilled in the art without departing from the spirit and scope of this creation as defined by the appended claims.

What is claimed is:

1. A hybrid portable power supply comprising:
a housing;
at least one rechargeable and dischargeable battery enclosed by the housing; and
a control circuit board being integrated in the housing;
wherein the housing is provided with a panel coupled to the control circuit board,
wherein the panel is provided with a plurality of power input/output connectors, a self-test switch, a circuit reset switch, an alarm device, a lighting device, and a charging connector,
wherein the control circuit board operates to control rectification and voltage conversion of power output from the rechargeable and dischargeable battery, such that power having at least a corresponding current or power having at least a corresponding voltage is output via one of the plurality of power input/output connectors, and
wherein the plurality of power input/output connectors include an emergency power connector via which power having a high instantaneous power value is output for supplying emergency power to vehicles.

2. The hybrid portable power supply according to claim 1, wherein the emergency power connector is connected to a power input port of a vehicle in need of emergency power by a removable power cable.

3. The hybrid portable power supply according to claim 2, wherein the emergency power connector is a modular quick connector having a foolproof mechanism.

4. The hybrid portable power supply according to claim 1, wherein the rechargeable and dischargeable battery is a LiFePO₄ battery.

5. The hybrid portable power supply according to claim 1, wherein the control circuit board is provided with a rectifier module and a voltage converter module to accordingly adjust a current value or a voltage value of the power output from the rechargeable and dischargeable battery.

6. The hybrid portable power supply according to claim 1, wherein the control circuit board operates to control the rectification and the voltage conversion of the power output from the rechargeable and dischargeable battery, such that one of the following power outputs is generated: power having a voltage of 5V, power having a voltage of 12V, power having a specified current value, and the power having a high instantaneous power value.

7. The hybrid portable power supply according to claim 1, wherein the plurality of power input/output connectors further include at least one of a USB DC power outlet, a constant current power outlet, and a vehicle cigarette lighter outlet.

8. The hybrid portable power supply according to claim 1, wherein the control circuit board is provided with a self-test module which is coupled to and activated by the self-test switch to test and display the rechargeable and dischargeable battery's power level.

9. The hybrid portable power supply according to claim 1, wherein the control circuit board is provided with a circuit reset module which is coupled to and activated by the circuit reset switch to control the resetting of the portable power supply.

10. The hybrid portable power supply according to claim 1, wherein the control circuit board is provided with a circuit breaker module which automatically cuts off power under one of the following circumstances: there is a short circuit in the portable power supply; there is a misconnection between the portable power supply and the vehicle in need of emergency power; the rechargeable and dischargeable battery is overcharged; and the rechargeable and dischargeable battery is over-discharged.

11. The hybrid portable power supply according to claim 1, wherein the alarm device is a buzzer which gives a warning tone in response to one of the following conditions: there is a short circuit in the portable power supply; and the rechargeable and dischargeable battery has a power level lower than a predetermined one.

12. The hybrid portable power supply according to claim 1, wherein the alarm device is an LED device comprising a plurality of LEDs, and the LED device activates a corresponding number of the LEDs to emit light according to a power level of the rechargeable and dischargeable battery.

13. The hybrid portable power supply according to claim 1, wherein the lighting device includes a multi-level lighting device which provides a desired illumination level according to actual needs.

14. The hybrid portable power supply according to claim 13, wherein the lighting device flashes on and off to give a warning in response to an emergency event.

15. The hybrid portable power supply according to claim 1, wherein the charging connector is adaptable to the following charging sources: a household electrical outlet, a power source compatible with universal voltage, a vehicle charging circuit, and a vehicle cigarette lighter.

16. The hybrid portable power supply according to claim 1, wherein the housing is formed by connecting a first housing and a second housing, and wherein the first housing is provided with a handle.
